(19) United States
(12) Patent Application Publication
(10) Pub. No.: US 2025/0283923 A1
(43) Pub. Date: Sep. 11, 2025

(54) Electrical Testing Apparatus

(71) Applicant: Robert John Fraser Reardon, London (GB)

(72) Inventor: Robert John Fraser Reardon, London (GB)

(21) Appl. No.: 19/073,115

(22) Filed: Mar. 7, 2025

(30) Foreign Application Priority Data
Mar. 7, 2024 (GB) 2403281.5

(51) Int. Cl. G01R 19/145

(52) U.S. Cl. CPC G01R 19/145

(57) ABSTRACT

A device for connection with a source of electrical power, current, and/or voltage is described wherein the device comprises an electrical light source or light bulb mounting having at least first and second electrical terminals arranged in electrical connection with, respectively, at least first and second sockets for connection with test leads. Kits comprising the device and methods of using the device are also described.

This application is a 35 U.S.C. § 111 patent application that claims the benefit of priority and is entitled to the filing date pursuant to 35 U.S.C. § 119 (a) of GB Patent Application 2403281.5, filed Mar. 7, 2024, the content of which is hereby incorporated by reference in its entirety.

Equipment for detection of the presence of electrical power, current, and or voltage are required by electricians, electrical engineers and other workers dealing with sources of electrical power.

Such a detection means may comprise a detector that utilises a portion of the electrical power in order to indicate the presence of electrical voltage, current, or power that has means for an electrical connection, preferably an electrically conducting connection between the source of electrical power and the detection means.

Thus, hitherto electrical engineers have utilised an apparatus comprising a lamp-bulb holder or mounting that is internally mounted in a housing with prongs extending therefrom that are in electrical connection with the lightbulb holder and thus the lightbulb therein. The prongs are made to extend to the source of electrical power, which is typically a generator and then to the load that is connected to the electrical generator. Accordingly, the device bridges the gap between the generator and the load. Ignition or lighting of the lamp-bulb indicates the presence of electricity (voltage, current and/or power) and thus provides the means of detection.

### SUMMARY

Aspects of the present specification disclose an apparatus or device and associated methods of application of the apparatus for detecting the presence of electrical power, currents, or voltage originating from a power source and being conducted to a low electrical load.

The disclosed device is used for connection with a source of electrical power, current, and/or voltage. The disclosed device can comprise an electrical light source or light bulb mounting having at least first and second electrical terminals arranged in electrical connection with, respectively, at least first and second sockets for connection with test leads. The disclosed device can have a lightbulb installed in the lightbulb mounting. The disclosed device can have the terminals of the lightbulb mounted in electrical connection to sockets for installation of test leads therein. The disclosed device can have the test leads can be configured in standard dimensions of multimeter test leads, the multimeter test leads can be shrouded at either end, and the shrouds can be 4 mm diameter banana plugs. The disclosed device can have the light source of lightbulb mounting is mounted on a base section, wherein the base is an insulating material. The disclosed device does not comprise a lightbulb.

The disclosed device can additionally comprise a cowl, cover, surrounding screen mounted on the base, or a handle of insulating material. The disclosed device can have the first and second electrical terminals arranged in electrical connection with, respectively, first and second sockets for connection with test leads. The disclosed device can have the cowl or cover has windows or portals therein. The disclosed device can have sockets for connection with test leads mounted to project through the material of the cowl, cover, or surround and/or sockets for connection with test leads are installed in or on the base section of the device.

Other aspects of the present specification disclose a kit comprising a device disclosed herein. The disclosed kit can additionally comprises a lightbulb and/or one or more test leads.

Yet other aspects of the present specification disclose a method for testing for electrical power, current, and/voltage using a device disclosed herein. The disclosed method can include the steps of a) installing a lightbulb in the mount of the device; b) connecting test leads to the device by installing plugs at the termini of the test leads in the cooperating sockets of the device, such that the test leads are in electrical connection with the lightbulb mounting of the device; and c) using one or more termini of the test leads to probe a source of electrical power.

### BRIEF DESCRIPTION OF THE DRAWINGS

The accompanying drawings, which are incorporated in and constitute a part of this specification, illustrate aspects of the disclosed subject matter in at least one of its exemplary embodiments, which are further defined in detail in the following description. Features, elements, and aspects of the disclosure are referenced by numerals with like numerals in different drawings representing the same, equivalent, or similar features, elements, or aspects, in accordance with one or more embodiments. The drawings are not necessarily to scale, emphasis instead being placed upon illustrating the principles herein described and provided by exemplary embodiments of the invention. More generally, those skilled in the art will appreciate that the drawings are schematic in nature and are not to be taken literally or to scale in terms of material configurations, sizes, thicknesses, and other attributes of an apparatus according to aspects of the present invention and its components or features unless specifically set forth herein. In such drawings:

FIG. 1 is a perspective diagram of an apparatus 100 as described in the Examples in which light-bulb holder 101 is mounted on base section 103. A shroud or surround 105 is connected to the base section around the area of the light-bulb holder. Red and black sockets 107 and 109 coloured red and black respectively, are mounted in the wall of the shroud or cover 105 and project through this wall. The sockets 107 and 109 are in electrical connection with the terminals of the light-bulb holder 101. The terminal of the electrical connections 107 and 109 are sockets for connection with test leads having cooperating plugs for insulation and installation within the sockets (not shown). A configuration of cooperating socket and plugs as used in this device is compatible with a multimeter, for example, those specified and manufactured by FLUKE®. Other configurations or dimensions of cooperating plugs and sockets may be used in the context of this disclosure;

FIG. 2 shows a diagram of a top view of the apparatus of FIG. 1;

FIG. 3 shows a cross-sectional diagram of the apparatus of FIGS. 1 & 2 through section A-A as marked in FIG. 2; and

FIG. 4 shows a diagram of a top view of the apparatus of FIGS. 1-3;

FIG. 5 shows a cross-sectional diagram of the apparatus of FIGS. 1-4 through section B-B as marked in FIGS. 2 & 4.

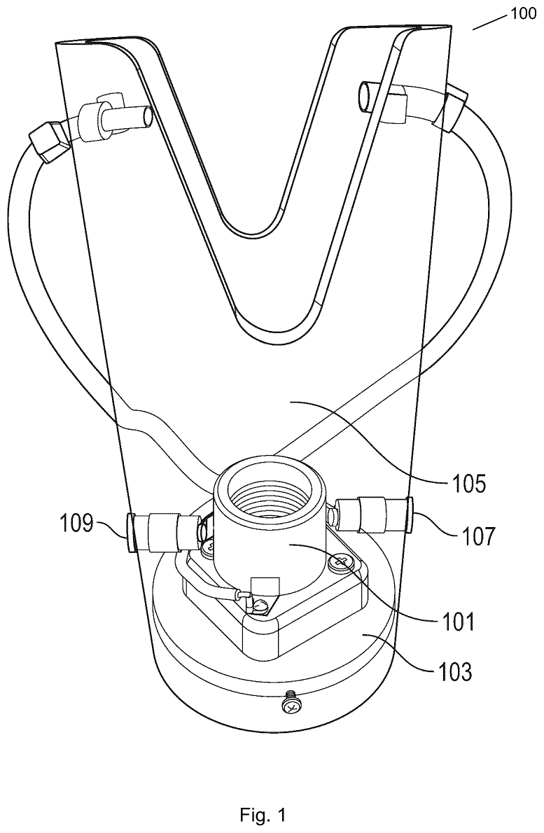

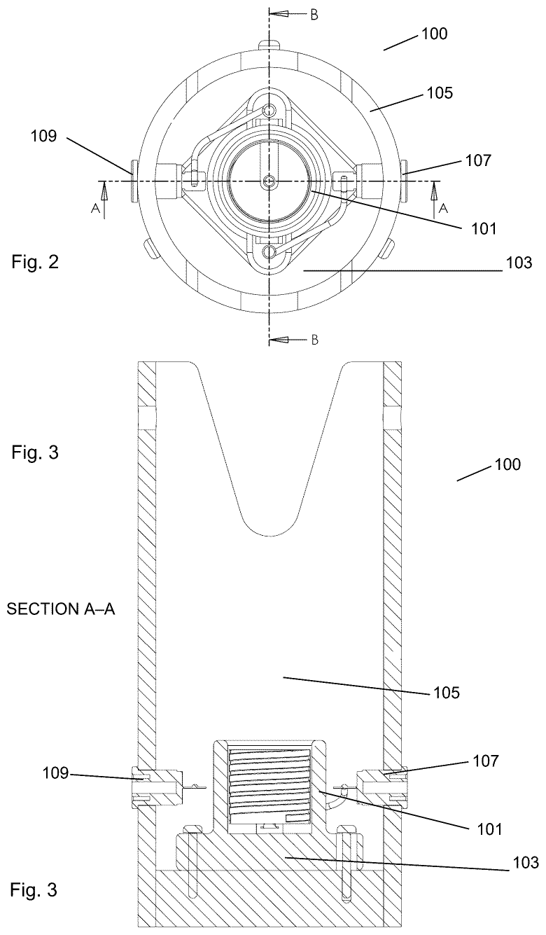

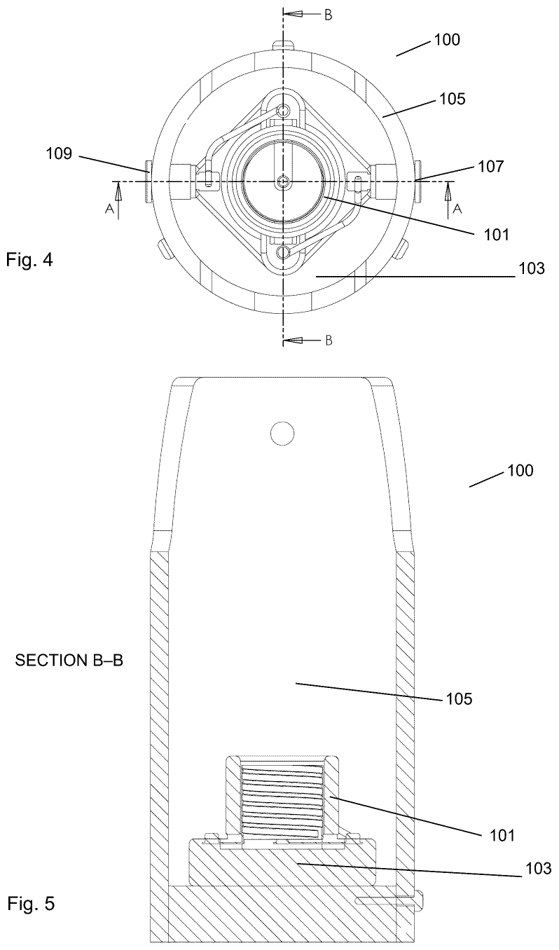

### DETAILED DESCRIPTION

An object of the invention is to produce an electrical testing apparatus that may be more safely and more conveniently deployed to test for the presence of electrical current. Additionally, an object of the invention is to provide an apparatus that comprises more easily interchangeable parts in order that the apparatus may be more easily repaired, adapted, and/or reused.

The invention provides a device for connection with a source of electrical power, current, and/or voltage, wherein the device comprises an electrical source or light bulb mounting having at least first and second electrical and terminals arranged in electrical connection with, respectively at least first and second sockets for connection with test leads.

In the context of the present disclosure as a light bulb is defined as a device used to convert electricity into light, comprising a source of illumination (e.g. an electrical filament or one or more light emitting diodes (LEDs) enclosed within a transparent or translucent shell. Typically a lightbulb has a rounded shape and is designed to be fitted into a socket in an electric lamp.

In the context of the present invention a socket is an opening or hollow that forms a holder for something. In the further context of this invention a socket is an electrical component designed to cooperate with a plug that is fitted and mounted therein in order to provide an electrical connection between the electrical terminus comprised in the socket and the electrical terminus or wire comprised in the plug section.

In the present context test leads are electrically conducting wires, preferably comprising a surrounding insulation wherein the termini of the leads comprise at one end a plug with an electrical terminus such that the plug can be mounted in a cooperating socket in order to provide an electrical connection between the socket and the test lead and wherein the remaining terminus of the test lead is electrically exposed in order to allow the user to form an electrical contact by touch or other electrical connection (e.g. using a further plug connection) with the electrical source, apparatus, and or circuit that is being tested.

Accordingly, the apparatus may be provided with a light bulb installed in the mounting therein.

The electrical terminals of the lightbulb mounting may be an electrical connection with sockets for installation of electrical test leads therein. A wide variety of test leads are available with a range of socket connects at their termini. A similarly wide range of sockets for connection of electrical test leads are also available. It is envisaged that any appropriate of cooperating plug and socket would be appropriate for use in the context of the device of the present invention. Preferably the test leads are multimeter test leads. Most preferably the test leads are of the configuration and standard dimensions of multimeter test leads. Advantageously test leads extend the capabilities of a multimeter. In this way the test leads may be connected to further fixings or apparatus such as clips, hooks or grabbers to yield a convenient and useful variety of test lead configurations as required.

Test leads, such as multimeter test leads, may have plugs or at one or both ends of the test leads, preferably both ends. The plugs may be banana plugs. Typically a banana plug is a single-conductor electrical plug comprising one or more banana-shaped members of spring metal at or near the tip of the plug. The plugs may be shrouded with insulating material. The shroud of insulating material is advantageous in terms of cleanliness of the plug thus contributing to more accurate and safer test readings. The plugs may be 4 mm diameter banana plugs mounted, or at one or both ends of the test leads, preferably both ends.

Termination of test leads with banana plugs or accommodating sockets advantageously allows for a variety of test lead configurations. The test leads may have a rubber coating or surface to provide electrical insulation. The rubber coating may be over moulded on surfaces of the test leads. This advantageously yields a comfortable and/or more reliable grip for the user of the test leads. This advantageously contributes to the ability of a user to make an accurate measurement. A preferred type of such test leads are FLUKE® TL224 leads. Accordingly, preferably the sockets comprised in the device described herein are sockets for connection with FLUKE® TL224 test leads.

In the context of the present invention an electrical supply may be characterised by being an alternating current (AC) or direct current (DC) current supply.

Furthermore the electrical supply described herein may be characterised as high voltage or low voltage in the context of ac high voltage would be typically greater than 1000 volts. Low voltage may be characterised as between 50-1000 volts and extra low voltage may be characterised as less than 50 volts. In the context of DC current high voltage might be characterised as greater than 1500 volts, low voltage may be characterised as between 120 and 1500 volts and extra low voltage may be characterised less than 120 volts. Accordingly, extra low voltages are of low risk. High voltages have the risk of electrical arching and low voltages have the risk of electrical shock delivered to an operator.

In a parallel sense high current and low current may be used in the context present device. High current causes the risk of danger arising from electrical shock or other electrical effects, whereas the risk from low current is significantly less [we might need a definition of high or low current here].

The mount for a light bulb may comprises terminals for connection to an electrical supply, preferably via an electrical connection through test leads that are in electrical connection with the terminals of the lightbulb mounting. In the context of the present invention a wide variety of light bulb mounts can be used in the context of the present invention. However, typically a standard lightbulb mount may be used. Thus the lightbulb mount may be an Edison screw type (e.g. “Edison”; or E27). Similarly, the standard lightbulb mount may be for a bayonet light bulb fitting (e.g. a standard B22 bayonet light bulb base).

The use of a light bulb is advantageous in that it provides in built fuse functionality. That is an excess of voltage of amperage will deliver a spike of power to the light bulb that will cause the filament or in-built electronics to exceed their rated capacity and thus fail, breaking the connection in what is effectively a controlled, or more controlled manner yields the benefit of greater safety to the operator while indicating by the spike of light intensity the nature of the failure. Accordingly, the use of particular light sources yields the advantage of the intensity or frequency of the light being emitted being related or measurable with respect to the current, voltage, and/or power being delivered to the light bulb by the electricity supply.

Accordingly, the present invention is utilisable with a wide range of voltages, currents, and/or powers and therefore is suitable, advantageously to a wide variety of electrical supply systems.

The device may also comprise a base on which the lightbulb mounting or light source may be mounted in addition, the test lead sockets may also be mounted on the base. Furthermore, the test lead sockets may be mounted such that they are mounted within the base and the electrical connections of the test sockets protrude through the base. This has the advantage of providing a more stable base for the test lead sockets and a closer connection with the terminals of the light bulb mounting or light source mounted on the base.

The device may additionally comprise a cover or surround screening or covering the electrical components mounted on the base from the exterior of the device. This has the advantage of preventing inadvertent contact and electrical shock or other dangers. The cowl or cover may be made from an insulating material. The insulating material may be a plastics material or polymer material. The material may be transparent or translucent. Such transparency or translucency yields the advantage of being able to conveniently assess the condition of the light source and gage changes in the light source simply and easily.

The cover or surrounding may have holes, windows, or portals through the material of the cowl or cover. Such windows may of a size to allow replacement of a light bulb in the mounting. The holes may be circular, elliptical, or polygonal. Alternatively or in addition the apertures may be connected to an edge of the cover or cowling. Thus the edge of a polygon or other shape may contact the edge of the cowling to form an open edge of the shape. The hole may therefore be a “cutout” section from the cowl. The shape of the cutout may be substantially triangular. The substantially triangular may be isosceles. The triangular cutout may have a rounded tip. The advantage of the triangular form is the ease of manufacturing. The advantage of the rounded tip is that this can be cut be using a circle cutter and thus also contributes to the ease of manufacturing. Furthermore, avoiding a sharp angle reduces the stress forces within the cover or cowling.

The base may be circular, square, or other polygonal form. The shape of the cowling or cover may match the shape of the base forming a hollow tube where the shape of the outer wall of the tube matches the shape of the base. A circular tube may therefore be used to be connected to a circular base section. This has the benefit of ease of manufacture and ease of fitting together.

The device may be provided with a supporting handle. The material f the handle may be insulating. Accordingly, the material of the handle may be a plastics material, rubber material or polymer material, or textile material, a composite material may be used of the handle. Thus the handle material may be a glass fibre material or carbon fibre material. Preferably the material of the handle is a “bungee” material comprising rubber strands stabilised using textile materials. The advantage of the insulating handle is that the device is isolated from the electric current and thus the risk of electrical arching and shock is reduced by the use of such an insulating handle.

Thus the invention provides a device as described herein additionally comprising a lightbulb in the lightbulb mounting comprised in the device.

Similarly the invention also provides a device without a lightbulb installed therein.

The invention further provides a kit comprising a device for connect with the source of electrical power, current, and/or voltage as described herein. The kit may additionally comprise test leads, preferably FLUKE® test leads, most preferably FLUKE® TL224 leads.

The kit may comprise a lightbulb for installation in the lightbulb mounting. The lightbulb may have an E27 (Edison) base (screw type).

The invention further provides a method for testing for the presence of electrical power, voltage, and/or current using a device as described herein wherein the method comprises the steps of: installing a lightbulb in the mount of the device; connecting test leads to the device by installing plugs at the termini of the test leads in the cooperating sockets of the device, such that the test leads are in electrical connection with the lightbulb mounting of the device; and using one or more termini of the test leads to probe a source of electrical power.

In the context of the present invention probe means to seek or test with the implication that the testing implement is used to probe the object of the test, i.e. by contacting a portion or part of the object under test.

### EXAMPLES

The following non-limiting examples are provided for illustrative purposes only in order to facilitate a more complete understanding of representative embodiments now contemplated. These examples should not be construed to limit any of the embodiments described in the present specification, including those pertaining to the apparatus or device, kit or methods.

### Example 1

An example of an apparatus for electrical testing comprises a lightbulb mounting on a base. The light bulb mounting may be of a standard light, e.g. an Edison (E27) or bayonet (B22) lightbulb mounting. The base the lightbulb holder is mounted on is preferably insulating or non-conducting.

Surrounding the lightbulb mount and preferably mounted to the base of the testing apparatus is a cover or shroud. This cover or shroud may be transparent or translucent in order to better view the bulb mounted in the lightbulb mounting.

The base of the apparatus may be circular in order to fit flush within a tube of translucent material that provides the wall of the cowl or surrounding cover.

Sections of the cowl or surrounding cover may be removed in order to allow the user access to the lightbulb mount in order that a lightbulb can be installed or removed from the lightbulb mount.

The lightbulb mounting has electrical terminals. Mounted within the walls of the device are sockets for electrical connection that are suitable for plug leads to be inserted into in order to provide an electrical connection between the termini and the test leads. The electrical termini installed in the walls of the cowl are linked in an electrical connection to the termini of the lightbulb mount.

Additionally, and optionally, a handle may be linked to the cover. Holes may be made in the cover for the material of the handle to eject therethrough. The material of the handle may be insulating and preferably is a rubber ‘bungee’ material.

### Example 2

In use, the apparatus described in Example 1 is set up by installation of a light bulb in the light bulb mount and plugging test leads with compatible plug ends into the sockets of the test apparatus.

The assembled apparatus is then used to test for the presence of electrical power by extended the test leads between the power source and the load. Lighting or otherwise ignition of the light bulb indicates the presence of electrical power, current or voltage depending on the test set up used.

Thus, the invention provides an improved or alternative apparatus for electrical testing.

1. A device for connection with a source of electrical power, current, and/or voltage, wherein the device comprises:
an electrical light source or light bulb mounting having at least first and second electrical terminals arranged in electrical connection with, respectively, at least first and second sockets for connection with test leads.

2. The device according to claim 1, wherein the first and second electrical terminals are arranged in electrical connection with, respectively, first and second sockets for connection with test leads.

3. The device according to claim 1, wherein the device has a lightbulb installed in the lightbulb mounting.

4. The device according to claim 1, wherein the terminals of the lightbulb mounting are inn electrical connection to sockets for installation of test leads therein.

5. The device according to claim 1, wherein the test leads are of the configuration and standard dimensions of multimeter test leads.

6. The device according to claim 5, wherein the multimeter test leads have shrouded, 4 mm diameter banana plugs at either end.

7. The device according to claim 1, wherein the light source of lightbulb mounting is mounted on a base section, wherein the base is an insulating material.

8. The device according to claim 1, wherein the device additionally comprises a cowl, cover, or surrounding screen mounted on the base.

9. The device according to claim 1 wherein the sockets for connection with test leads are mounted to project through the material of the cowl, cover, or surround.

10. The device according to claim 1 wherein the sockets for connection with test leads are installed in or on the base section of the device.

11. The device according to claim 1, wherein the device additionally comprises a handle of insulating material.

12. The device according to claim 1 wherein the cowl or cover has windows or portals therein.

13. The device according to claim 1 wherein the device does not comprise a lightbulb.

14. A kit comprising a device according to claim 1.

15. The kit as claimed in claim 14, wherein the kit additionally comprises a lightbulb.

16. The kit as claimed in claim 14, wherein the kit additionally comprises a test lead.

17. The kit as claimed in claim 16, wherein the kit the test lead comprises two test leads.

18. A method for testing for electrical power, current, and/voltage using a device of claim 1, wherein the method comprises the steps of:
a) installing a lightbulb in the mount of the device;
b) connecting test leads to the device by installing plugs at the termini of the test leads in the cooperating sockets of the device, such that the test leads are in electrical connection with the lightbulb mounting of the device; and
c) using one or more termini of the test leads to probe a source of electrical power.
